(19) United States
(12) Patent Application Publication
(10) Pub. No.: US 2008/0116530 A1
(43) Pub. Date: May 22, 2008

(54) Semiconductor Devices Having Transistors with Different Gate Structures and Related Methods

(75) Inventors: Sang-jin Hyun, Gyeonggi-do (KR); Si-young Choi, Gyeonggi-do (KR); In-sang Jeon, Seoul (KR); Sang-bom Kang, Seoul (KR); Hye-min Kim, Gyeonggi-do (KR)

Correspondence Address: MYERS BIGEL SIBLEY & SAJOVEC, PO BOX 37428, RALEIGH, NC, 27627, US

(73) Assignee: Samsung Electronics Co., Ltd.

(21) Appl. No.: 11/855,413

(22) Filed: Sep. 14, 2007

(30) Foreign Application Priority Data
Nov. 22, 2006 (KR) 2006-0115891

(51) Int. Cl. H01L 29/94; H01L 21/8238

(52) U.S. Cl. 257/410; 257/E27.084; 257/E21.646; 438/216

(57) ABSTRACT

A semiconductor device may include a semiconductor substrate and first and second transistors. The first transistor may have a first gate structure on the semiconductor substrate, and the first gate structure may include a first gate insulating layer between a first gate electrode and the semiconductor substrate. The first gate insulating layer may include first and second dielectric materials with the second dielectric material having a greater dielectric constant than the first dielectric material. Moreover, the first gate electrode may be in contact with the second dielectric material. The second transistor may have a second gate structure on the semiconductor substrate, with the second gate structure including a second gate insulating layer between a second gate electrode and the semiconductor substrate. Related methods are also discussed.

### RELATED APPLICATION

This application claims priority from Korean Patent Application No. 10-2006-0115891 filed on Nov. 22, 2006 in the Korean Intellectual Property Office, the disclosure of which is incorporated herein by reference in its entirety.

### FIELD OF THE INVENTION

The present invention relates to electronics and, more particularly, to semiconductor electronic devices and related methods.

### BACKGROUND

Semiconductor devices such as DRAM devices are volatile memory devices providing relatively fast data input and output wherein data may be lost over a period of time. Accordingly, the devices may be periodically refreshed to preserve the stored data. With increases in cell integration of DRAM devices, an unwanted memory cell may be frequently turned on during refresh periods. A resulting transmission of data to an unwanted cell and/or loss of data may reduce reliability of the device.

An increased threshold voltage of a transistor may reduce an effect on an unselected cell when an adjacent cell is turned on. For example, an impurity may be doped into a channel area to increase a threshold voltage of a channel area. When an impurity is doped into the channel area, however, a junction leakage may increase in the channel area. An increase in junction leakage may reduce a storage time of data in the memory cell. If the storage time of data is reduced, refresh operations may need to be performed more frequently. More frequent refresh operations, however, may reduce processing speeds of the DRAM device.

### SUMMARY

According to some embodiments of the present invention, a semiconductor device may include a semiconductor substrate and first and second transistors. The first transistor may have a first gate structure on the semiconductor substrate. More particularly, the first gate structure may include a first gate insulating layer between a first gate electrode and the semiconductor substrate, and the first gate insulating layer may include first and second dielectric materials with the second dielectric material having a greater dielectric constant than the first dielectric material. Moreover, the first gate electrode may be in contact with the second dielectric material. The second transistor may have a second gate structure on the semiconductor substrate, and the second gate structure may include a second gate insulating layer between a second gate electrode and the semiconductor substrate.

The first gate insulating layer may include a layer of the second dielectric material between a layer of the first dielectric material and the first gate electrode, and the layer of the second insulating material may have a thickness in the range of about 4 Angstroms to about 20 Angstroms. The first gate insulating layer may include an interface region adjacent the first gate electrode, and the interface region may include the first and second dielectric materials. More particularly, the interface region may include a mixture of the first and second dielectric materials.

The second dielectric material may include a metal oxide such as HfO₂, HfSiOₓ, HfSiON, HfAlO, HfYO, HfLaO, HfTiO, and/or HfTaO. The first dielectric material may include silicon oxide, silicon nitride, and/or silicon oxynitride. Moreover, a thickness of the first gate insulating layer may be greater than a thickness of the second gate insulating layer. In addition, the second gate insulating layer may be free of the second dielectric material.

The substrate may include a memory cell area and a peripheral circuit area, the first transistor may be a memory cell access transistor in the memory cell area, and the second transistor may be a peripheral circuit transistor in the peripheral circuit area. The first transistor may include source/drain regions of the semiconductor substrate on opposite sides of the first gate structure and a channel region between the source/drain regions. The channel region may define a recess in a surface of the semiconductor substrate with portions of the first gate insulating layer and the first gate electrode in the recess, or the channel region may protrude from a surface of the semiconductor substrate. Moreover, a memory cell capacitor may include first mid second capacitor electrodes separated by a capacitor dielectric, and the first capacitor electrode may be electrically coupled to one of the source/drain regions of the first transistor.

According to some other embodiments of the present invention, a method of forming a semiconductor device may include providing a semiconductor substrate and forming first and second transistors on the semiconductor substrate. The transistor may have a first gate structure including a first gate insulating layer between a first gate electrode and the semiconductor substrate. The first gate insulating layer may include first and second dielectric materials with the second dielectric material having a greater dielectric constant than the first dielectric material. Moreover, the first gate electrode may be in contact with the second dielectric material. The second transistor may have a second gate structure on the semiconductor substrate, and the second gate structure may include a second gate insulating layer between a second gate electrode and the semiconductor substrate.

The first gate insulating layer may include a layer of the second dielectric material between a layer of the first dielectric material and the first gate electrode, and the layer of the second insulating material may have a thickness in the range of about 4 Angstroms to about 20 Angstroms. The first gate insulating layer may include an interface region adjacent the first gate electrode with the interface region including the first and second dielectric materials, and the interface region may include a mixture of the first and second dielectric materials. The second dielectric material may include a metal oxide such as HfO₂, HfSiOₓ, HfSiON, HfAlO, HfYO, HfLaO, HfTiO, and/or HfTaO, and the first dielectric material may include silicon oxide, silicon nitride, and/or silicon oxynitride.

According to some embodiments of the present invention, a threshold voltage of a semiconductor memory device may be increased without significantly increasing junction leakage.

According to some embodiments of the present invention, a semiconductor memory device may include a semiconductor substrate having a first area and a second area; a first gate structure having a first gate insulating layer and a first gate electrode formed in the first area of the semiconductor substrate; and a second gate structure having a second gate insulating layer and a second gate electrode formed in a second area of the semiconductor substrate. The first gate insulating layer may include a first dielectric substance and a second dielectric substance having a dielectric constant larger than a dielectric constant of the first dielectric substance. Moreover, a first gate electrode may come into contact with the second dielectric substance.

According to other embodiments of the present invention, a method of forming a semiconductor device may include providing a semiconductor substrate including a first area and a second area; forming a first gate structure including a first gate insulating layer and a first gate electrode in the first area of the semiconductor substrate; and forming a second gate structure including a second gate insulating layer and a second gate electrode in the second area of the semiconductor substrate. The first gate insulating layer may include a first dielectric substance and a second dielectric substance having a dielectric constant larger than a dielectric constant of the first dielectric substance. The first gate electrode may come into contact with the second dielectric substance.

### BRIEF DESCRIPTION OF THE DRAWINGS

The above and other features and advantages of the present invention will become more apparent by describing in detail embodiments thereof with reference to the attached drawings in which:

FIG. 1 is a cross sectional view of a semiconductor device including a gate structure according to some embodiments of the present invention;

FIG. 2 is a cross sectional view of a semiconductor device including a gate structure according to some other embodiments of the present invention;

FIG. 3 is a cross sectional view of a DRAM device including the gate structure of FIG. 1;

FIGS. 4 and 5 are cross sectional views of the gate structures of semiconductor devices according to still other embodiments of the present invention;

FIG. 6 is a perspective view of a gate structure of semiconductor devices according to embodiments of the present invention; and

FIGS. 7 to 9 are cross sectional views of intermediate structures during a process of fabricating the gate structure of FIG. 1.

### DETAILED DESCRIPTION

The present invention is described more fully hereinafter with reference to the accompanying drawings, in which embodiments of the present invention are shown. This invention may, however, be embodied in many different forms and should not be construed as limited to the embodiments set forth herein. Rather, these embodiments are provided so that this disclosure will be thorough and complete, and will fully convey the scope of the present invention to those skilled in the art. In the drawings, the sizes and relative sizes of layers and regions may be exaggerated for clarity. Like numbers refer to like elements throughout.

It will be understood that when an element or layer is referred to as being “on”, “connected to” or “coupled to” another element or layer, it can be directly on, connected or coupled to the other element, or layer or intervening elements or layers may be present. In contrast, when an element is referred to as being “directly on,” “directly connected to” or “directly coupled to” another element or layer, there are no intervening elements or layers present. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly. Also, as used herein, “lateral” refers to a direction that is substantially orthogonal to a vertical direction.

The terminology used herein is for the purpose of describing particular embodiments only, and is not intended to be limiting of the present invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments of the present invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present invention.

Unless otherwise defined, all terms (including technical and scientific terms) used herein have the same meaning as commonly understood by one of ordinary skill in the art to which this invention belongs. Accordingly, these terms can include equivalent terms that are created after such time. It will be further understood that terms, such as those defined in commonly used dictionaries, should be interpreted as having a meaning that is consistent with their meaning in the present specification and in the context of the relevant art, and will not be interpreted in an idealized or overly formal sense unless expressly so defined herein. All publications, patent applications, patents, and other references mentioned herein are incorporated by reference in their entirety.

Hereinafter, semiconductor devices according to embodiments of the present invention will be described with reference to the accompanying drawings.

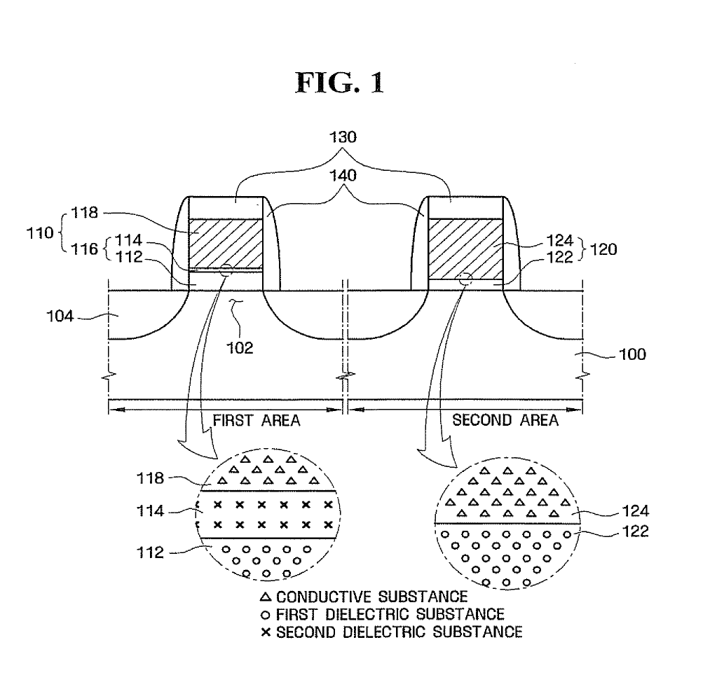

FIG. 1 is a cross sectional view of a semiconductor device including a gate structure according to some embodiments of the present invention.

With reference to FIG. 1, the semiconductor device includes a plurality of gate structures 110 and 120 formed on a same semiconductor substrate 100. The semiconductor substrate may include at least two areas that are separated from each other, with different gate structure types in the different areas. For example, as shown in FIG. 1, the semiconductor substrate 100 may be divided into a first area where the first gate structure 110 is formed and a second area where the second gate structure 120 is formed.

The first gate structure 110 includes a first gate insulating layer 116, and a first gate electrode 118 on the first gate insulating layer. The second gate structure 120 includes a second gate insulating layer 122, and a second gate electrode 124 on the second gate insulating layer.

The first gate electrode 118 and the second gate electrode 124 include a conductive material, such as a metal, a metal silicide, and/or doped polysilicon. Each of first gate electrode 118 and the second gate electrode 124 may have a single layer structure including one of the above-mentioned conductive materials, or a multilayered structure including layers of two or more of the above mentioned materials.

The structures and the constituent materials of the first gate electrode 118 and the second gate electrode 124 may be the same as each other Structures of the first gate insulating layer 116 and the second gate insulating layer 122, however, may be different as discussed in greater detail.

The first gate insulating layer 116 may include first and second dielectric materials. The first dielectric material may have a dielectric constant of about 4.0. The first dielectric material, for example, may include silicon oxide, silicon nitride, and/or silicon oxynitride.

The second dielectric material may have a dielectric constant that is greater than that of the first dielectric material, and the dielectric constant of the second dielectric material may be greater than about 4.0. The second dielectric material may be a metal oxide. More particularly, the second dielectric material may be a hafnium oxide such as HfO₂, HfSiOₓ, HfSiON, HfAlO, HfYO, HfLaO, HfTiO, and/or HfTaO.

The first gate insulating layer 116 may have a structure including a lower gate insulating layer 112 and an upper gate insulating layer 114. The lower gate insulating layer 112 may be formed of the first dielectric material and the upper gate insulating layer 114 may be formed of the second dielectric material. Accordingly, the first gate electrode 118 may come into direct contact with the upper gate insulating layer 114 of the first gate insulating layer 116, and the conductive material of the first gate electrode 118 may come into direct contact with the second dielectric material of the upper gate insulating layer 114.

The upper gate insulating layer 114 may increase a threshold voltage of the first gate structure 110 as described below. A relatively thin upper gate insulating layer 114 may be used to increase the threshold voltage. The increase in threshold voltage of the upper gate insulating layer 114 may be primarily caused by contact between the second dielectric material and the conductive material so that if the thickness of at least one gate insulating layer is assured, the threshold voltage may be increased. For example, a thickness of the upper gate insulating layer 114 may be in the range of about 4 Å (angstrom) to about 20 Å (angstrom).

The second gate insulating layer 122 may include a third dielectric material, and the second gate insulating layer 122 may have a single layer structure that is made of the third dielectric material. The third dielectric material may have a dielectric constant of about 4.0, like the first dielectric material discussed above with respect to the lower gate insulating layer 112. The third dielectric material of the second gate insulating layer 122 may be the same as the first dielectric material of the first gate insulating layer 116.

A total thickness of the first gate insulating layer 116 may be larger than the thickness of the second gate insulating layer 122. Moreover, the thickness of the lower gate insulating layer 112 of the first gate insulating layer 116 may be greater than the thickness of the second gate insulating layer 122.

Channel areas 102 may be formed under the first gate structure 110 and the second gate structure 120. The channel areas 102 are formed in the semiconductor substrate 100, and source/drain areas 104 doped with an n-type impurity or a p-type impurity at a relatively high concentration may be provided at opposite sides of the channel areas 102. In some embodiments of the present invention, the source/drain areas 104 may be aligned at edges of the first and second gate structures 110 and 120. In other embodiments of the present invention, the source/drain areas 104 may be provided so that portions of the source/drain areas are diffused beyond edges of the first and second gate structures 110 and 120. In this case, the source/drain areas 104 may partially overlap the first and second gate strictures 110 and 120.

Optionally, insulating layers for a hard mask 130 may be formed on upper portions of the first and second gate structures 110 and 120, and spacers 140 may be provided on sidewalls of the first and second gate structures 110 and 120. The semiconductor device that is shown in FIG. 1 may provide different threshold voltages according to the gate structures 110 and 120 that are formed in the different areas. More particularly, a threshold voltage at which the channel area 102 under the second gate structure 120 is turned on by the second gate structure 120 may be the same as a threshold voltage determined based on a dielectric constant and a thickness of the second gate insulating layer 122.

A threshold voltage at which the channel area 102 under the first gate structure 110 is turned on by the first gate structure 110 may be greater than a threshold voltage determined according to the dielectric constant and the thickness of the first gate insulating layer 116. That is, in the case of the first gate structure 110, the first gate electrode 118 may come into direct contact with the upper gate insulating layer 114. If the conductive material of the first gate electrode 118 comes into contact with the high dielectric material of the upper gate insulating layer 114, Fermi pinning may occur. Fermi pinning may increase a threshold voltage of the NMOS transistor.

When the conductive material of the first gate electrode 118 is polysilicon and the second dielectric material is HfO₂ so that HfO₂ is in direct contact with polysilicon, for example, a threshold voltage of the NMOS transistor may be increased to about 200 mV. It is believed that the increase in threshold voltage may be due to a resulting reduction in a Fermi level of polysilicon due to HfO₂ that comes into direct contact with polysilicon. That is, in this case, it is believed that the Fermi level of polysilicon may be pinned to about 200 mV.

Therefore, in the case of the first area, a threshold voltage of the NMOS transistor may be increased without increasing a doping concentration of the impurity of the channel area 102. An increase in doping concentration of the channel area 102 may increase junction leakage. Since the threshold voltage may be increased without increasing a doping concentration in the channel area, the threshold voltage may be increased without significantly increasing junction leakage.

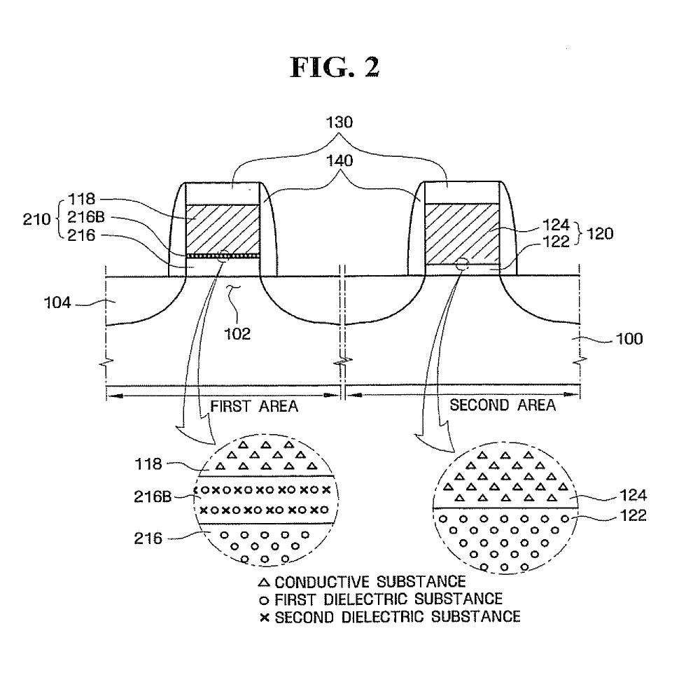

In the above-mentioned embodiments of FIG. 1, the first gate insulating layer 116 of the first gate structure 110 may be divided into the lower gate insulating layer 112 and the upper gate insulating layer 114. Since the threshold voltage of the first area is increased due to Fermi pinning resulting from a reaction between the conductive substance of the first gate electrode 118 and the high dielectric material, a same or similar effect may be obtained as long as the conductive substance comes into contact with the high dielectric material. An example thereof is shown in FIG. 2.

FIG. 2 is a cross sectional view of a semiconductor device that includes a gate structure according to other embodiments of the present invention. The semiconductor device of FIG. 2 is similar to that of FIG. 1 in that a first gate structure 210 of the first area includes a first gate insulating layer 216 and a first gate electrode 118. However, the structure of the first gate insulating layer 216 is different from that of the first gate insulating layer 116 of FIG. 1.

As shown in FIG. 2, the first gate insulating layer 216 may include the first dielectric material and the second dielectric material but the first and second dielectric materials may not be sharply separated from each other in different layers. For example, the first dielectric material and the second dielectric material may be uniformly distributed while being mixed with each other. Alternatively, only the first dielectric material may be provided in the lower part of the first gate insulating layer 216, and the first dielectric material and the second dielectric material may be mixed with each other in the upper part of the first gate insulating layer 216. However, in both cases, at least the upper surface of the first gate insulating layer 216 which comes into contact with the first gate electrode 118 (that is, the interface 216B between the first gate electrode 118 and the first gate insulating layer 216) includes the second dielectric material.

As described above, when the second dielectric material is included in the interface 216B between the first gate electrode 118 and the first gate insulating layer 216, even though the first dielectric material and the second dielectric material are mixed with each other at the interface 216B without separating the layers, the second dielectric material may be selectively reacted with the conductive material of the first gate electrode 118 to cause Fermi pinning. Accordingly, a threshold voltage applied to turn on the channel area 102 under the first gate structure 210 may be increased.

In the case of embodiments of FIG. 2, since the threshold voltage is increased without increasing the doping concentration of the channel area 102 in the first area, an increase of the junction leakage may be reduced and the threshold voltage may be increased.

In embodiments of FIGS. 1 and 2, a reduced increase in junction leakage and increase in threshold voltage in the first area may improve operation characteristics of, for example, a cell area of the DRAM device. Meanwhile, since second areas of the embodiments of FIGS. 1 and 2 have a threshold voltage that is determined according to the type of dielectric material providing the second gate insulating layer and the thickness of the second gate insulating layer, the second area may have a relatively lower threshold voltage in comparison with the first area. Additionally, when a thickness of the second gate insulating layer is less than that of the first gate insulating layer, a difference in the relative size of threshold voltage may be increased. The second area that has the lower threshold voltage may be usefully applied to, for example, a peripheral circuit area of the DRAM device, which may require rapid operation characteristics. Accordingly, embodiments of FIGS. 1 and 2 may be usefully applied to a DRAM device including a cell area and a peripheral circuit area.

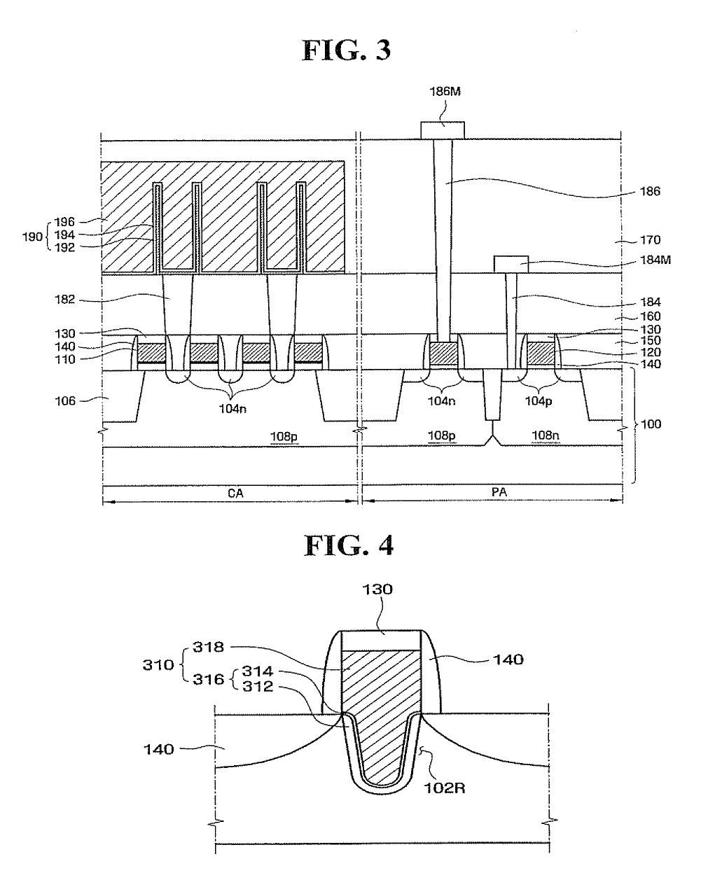

FIG. 3 illustrates a DRAM device that includes a first gate structure and a second gate structure according to embodiments of FIG. 1. However, the DRAM device of FIG. 3 is given to illustrate only some embodiments of the present invention. Accordingly, the DRAM device of FIG. 3 may include a first gate structure and a second gate structure according to embodiments of FIG. 2.

With reference to FIG. 3, a semiconductor substrate may be divided into a cell area (CA) and a peripheral circuit area (PA). The peripheral circuit area (PA) may include a peripheral area and a core area.

A plurality of memory cells that each include an NMOS transistor and a capacitor 190 may be formed in the cell area (CA). More particularly, p-type well 108p may be formed in the semiconductor substrate 100 at the cell area (CA), and the first gate structures 110 may be formed on the p-type well 108p. Channel areas may be provided under the first gate structures 110, and n-type source/drain areas 104n (into which an n-type impurity is doped) are disposed at opposite sides of the channel area. A first gate structure 110, a respective channel area, and respective n-type source/drain areas 104n constitute an NMOS transistor.

A capacitor 190 including a lower conductive layer 192, a dielectric layer 194, and an upper conductive layer 196 may be formed on each NMOS transistor. Each capacitor 190 may be electrically connected through a capacitor contact plug 182 to a respective n-type source/drain area 104n. Reference numeral 106 denotes an isolation layer, reference numeral 150 denotes a first interlayer insulating layer, reference numeral 160 denotes a second interlayer insulating layer, and reference numeral 170 denotes a third interlayer insulating layer.

NMOS and PMOS transistors may be formed in the peripheral circuit area (PA). That is, a p-type well 108p and an n-type well 108n may be formed in the semiconductor substrate 100 of the peripheral circuit area (PA), and the second gate structures 120 may be formed on the wells 108p and 108n. A channel area may be provided under each second gate structure 120. N-type source/drain areas 104n (into which an n-type impurity is doped at a relatively high concentration) may be provided at both sides of the channel area of the p-type well 108p. P-type source/drain areas 104p (doped with a p-type impurity at a relatively high concentration) may be provided at both sides of the channel area of the n-type well 108n.

A first metal wire 184M (formed on the second interlayer insulating layer 160 of the peripheral circuit area (PA)) may be electrically connected through a first metal contact plug 184 to a p-type source/drain area 104p. A second metal wire 186M (formed on the third interlayer insulating layer 170) may be electrically connected through a second metal contact plug 186 to a second gate metal of a second gate structure 120.

In the cell area (CA) of the DRAM device, memory cells may be disposed closely adjacent to each other. Accordingly, when the threshold voltage is relatively low and a predetermined NMOS transistor is turned on, neighboring cells may be affected. In particular, during a dynamic refresh operation when unwanted cells are turned on, data may be removed or written. Therefore, a relatively high threshold voltage of the NMOS transistor may be desired in the cell area (CA). With respect to the cell area (CA) of the DRAM device, data is stored in the capacitors 190. If the junction leakage increases, a storage time of data may be reduced thereby reducing a refresh cycle period and reducing processing speed of the DRAM device and/or reliability.

Accordingly, the first gate structure 110 of FIG. 1 may be applied to the cell area (CA) of the DRAM device to provide memory cells in which threshold voltages are relatively high and junction leakage is relatively low.

Meanwhile, in the peripheral circuit area (PA) of the DRAM device, a distance between the transistors may be relatively greater, and capacitors used to store data are not provided. The peripheral area may require rapid operation of the circuits. Therefore, the second gate structure 120 of FIG. 1 may be applied to the peripheral circuit area (PA) of the DRAM device to provide relatively rapid operation.

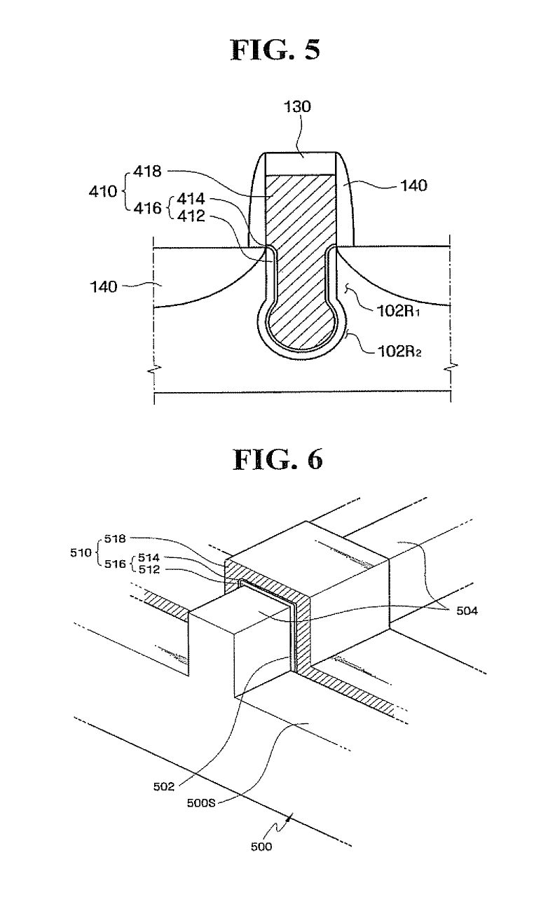

In the above-mentioned semiconductor devices, a channel area may have a plane structure. However, embodiments of the present invention are not limited to plane structures. In other embodiments of the present invention, the channel area may have a three dimensional structure. FIGS. 4 and 5 are cross sectional views of gate structures of semiconductor devices according to some other embodiments of the present invention. FIG. 6 is a perspective view of gate structures of semiconductor devices according to still other embodiments of the present invention. The cross sectional views and the perspective view that are illustrated in FIGS. 4 to 6 correspond to the first area of FIG. 1. In FIGS. 4 to 6, the second area may have the same structure as the second area of FIG. 1.

The semiconductor device that is illustrated in FIG. 4 may include a recess area 102R that is formed by recessing at least a portion of the channel area relative to the surface of the semiconductor substrate. A bottom surface of the first gate structure 310 may be conformally formed along the recess area 102R. The recess area 102R may contribute to an increase in length of the channel area, thereby reducing short channel effects.

The semiconductor device of FIG. 5 may include recess areas 102R1 and 102R2 that are formed by recessing at least a portion of the channel area with respect to the surface of the semiconductor substrate. The first recess area 102R1 may be substantially linear, and the second recess area 102R2 may be substantially spherical. A bottom surface of the first gate structure 410 may be conformally formed along the recess areas 102R1 and 102R2. In the present embodiments, the recess areas 102R1 and 1021R2 may contribute to an increase in length of the channel area, thereby reducing short channel effects.

In the semiconductor device that is illustrated in FIG. 6, the channel area 502 protrudes from the surface 500S of the semiconductor substrate 500 that is adjacent to the channel area, and the first gate structure 510 covers the surface of the protruding channel area 502. The protruding channel area 502 contributes to the formation of the channel area having two or more sides, thereby increasing a width of the channel area.

Like the first gate structure that is shown in FIG. 1, in the embodiments of FIGS. 4 to 6, the first gate insulating layers 316, 416, and 516 may include the lower gate insulating layers 312, 412, and 512 of the first dielectric material, and the upper gate insulating layers 314, 414, and 514 of the second dielectric material. Accordingly, a threshold voltage may be increased due to Fermi pinning between the first gate insulating layers 316, 416, and 516 and the first gate electrodes 318, 418, and 518 that come into contact with the first gate insulating layers 316, 416, and 516. In addition, since the increase in threshold voltage is not caused by the doping of the impurity in the channel area, an increase in junction leakage may be reduced and/or prevented. Semiconductor devices according to embodiments of FIGS. 4 to 6 may be combined with embodiments of FIGS. 2 and 3.

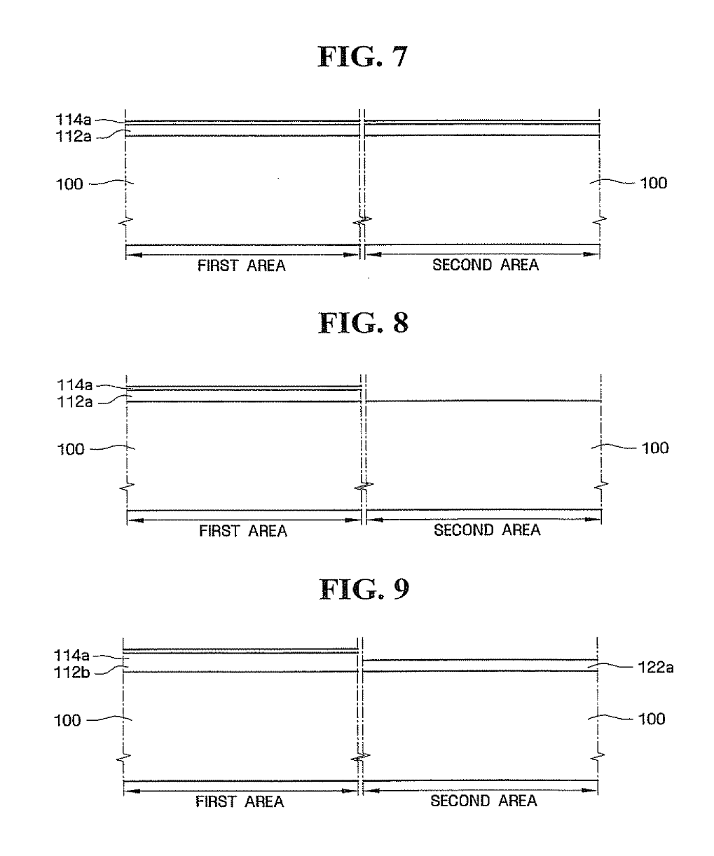

Hereinafter, an example of a method of fabricating a semiconductor device according to embodiments of the present invention will be described. FIGS. 7 to 9 are cross sectional views of intermediate structures in a process of fabricating the gate structure of FIG. 1.

With reference to FIG. 7, a first dielectric material layer 112a and a second dielectric material layer 114a are sequentially formed on the semiconductor substrate 100 including the first area and the second area. When the first dielectric material layer 112a is made of silicon oxide, the semiconductor substrate 100 may be oxidized by heating to form the resulting semiconductor substrate with the first dielectric material layer 112a and the second dielectric material layer 114a. When the second dielectric material layer 114a is made of a metal oxide such as HfO₂, the layer 114a may be formed using a process such as a low pressure CVD (LPCVD) process, an atomic layer deposition (ALD) process, a physical vapor deposition (PVD) process, and/or a metal organic CVD (MOCVD) process.

With reference to FIG. 8, portions of the first dielectric material layer 112a and the second dielectric material layer 114a on the second area may be removed. The removing may be performed, for example, using a wet etch process with a mask.

With reference to FIG. 9, a third dielectric layer 122a may be formed on the second area. When the third dielectric material layer 122a is made of silicon oxide, an entire surface of the semiconductor substrate 100 may be oxidized by heating to form the third dielectric material layer 122a that is made of silicon oxide on the exposed second area. In this process, the first dielectric material layer 112b of the first area may be additionally oxidized so that a thickness of the first dielectric material layer may be increased. Subsequent processes may be performed using methods known in the art.

To fabricate the semiconductor device of FIG. 2, the first dielectric material and the second dielectric material may be simultaneously deposited, and/or the second dielectric material may be deposited while the first dielectric material is oxidized by heating in the process shown in FIG. 7. This is set forth to illustrate embodiments of the present invention, but is not to be construed as limiting the present invention.

Semiconductor devices according to embodiments of FIGS. 3 to 6 may be formed using methods described with reference to FIGS. 7 to 9.

In semiconductor devices according to some embodiments of the present invention, threshold voltage may be increased without significantly increasing junction leakage due to a reaction between a high dielectric material of a first gate structure and a conductive gate electrode material in a first area. In addition, a typical threshold voltage may be maintained in a second area. That is, in semiconductor devices according to some embodiments of the present invention, it may be possible to selectively control the threshold voltage according to the area.

While the present invention has been particularly shown and described with reference to embodiments thereof, it will be understood by those of ordinary skill in the art that various changes in form and details may be made therein without departing from the spirit and scope of the present invention as defined by the following claims.

What is claimed is:

1. A semiconductor device comprising:
a semiconductor substrate;
a first transistor having a first gate structure on the semiconductor substrate, the first gate structure including a first gate insulating layer between a first gate electrode and the semiconductor substrate, wherein the first gate insulating layer includes first and second dielectric materials, wherein the second dielectric material has a greater dielectric constant than the first dielectric material, and wherein the first gate electrode is in contact with the second dielectric material; and
a second transistor having a second gate structure on the semiconductor substrate, the second gate structure including a second gate insulating layer between a second gate electrode and the semiconductor substrate.

2. A semiconductor device according to claim 1 wherein the first gate insulating layer includes a layer of the second dielectric material between a layer of the first dielectric material and the first gate electrode.

3. A semiconductor device according to claim 2 wherein the layer of the second insulating material has a thickness in the range of about 4 Angstroms to about 20 Angstroms.

4. A semiconductor device according to claim 1 wherein the first gate insulating layer includes an interface region adjacent the first gate electrode wherein the interface region includes the first and second dielectric materials.

5. A semiconductor device according to claim 4 wherein the interface region comprises a mixture of the first and second dielectric materials.

6. A semiconductor device according to claim 1 wherein the second dielectric material comprises a metal oxide.

7. A semiconductor device according to claim 6 wherein the metal oxide comprises HfO₂, HfSiOₓ, HfSiON, HfAlO, HfYO, HfLaO, HfTiO, and/or HfTaO.

8. A semiconductor device according to claim 1 wherein the first dielectric material comprises silicon oxide, silicon nitride, and/or silicon oxynitride.

9. A semiconductor device according to claim 1 wherein a thickness of the first gate insulating layer is greater than a thickness of the second gate insulating layer.

10. A semiconductor device according to claim 1 wherein the substrate includes a memory cell area and a peripheral circuit area, wherein the first transistor is a memory cell access transistor in the memory cell area, and wherein the second transistor is a peripheral circuit transistor in the peripheral circuit area.

11. A semiconductor device according to claim 1 wherein the first transistor includes source/drain regions of the semiconductor substrate on opposite sides of the first gate structure and a channel region between the source/drain regions.

12. A semiconductor device according to claim 11 wherein the channel region defines a recess in a surface of the semiconductor substrate and wherein portions of the first gate insulating layer and the first gate electrode are in the recess.

13. A semiconductor device according to claim 11 wherein the channel region protrudes from a surface of the semiconductor substrate.

14. A semiconductor device according to claim 11 further comprising:
a memory cell capacitor including first and second capacitor electrodes separated by a capacitor dielectric, wherein the first capacitor electrode is electrically coupled to one of the source/drain regions of the first transistor.

15. A semiconductor device according to claim 1 wherein the second gate insulating layer is free of the second dielectric material.

16. A method of forming a semiconductor device, the method comprising:
providing a semiconductor substrate;
forming a first transistor having a first gate structure on the semiconductor substrate, the first gate structure including a first gate insulating layer between a first gate electrode and the semiconductor substrate, wherein the first gate insulating layer includes first and second dielectric materials, wherein the second dielectric material has a greater dielectric constant than the first dielectric material, and wherein the first gate electrode is in contact with the second dielectric material; and
forming a second transistor having a second gate structure on the semiconductor substrate, the second gate structure including a second gate insulating layer between a second gate electrode and the semiconductor substrate.

17. A method according to claim 16 wherein the first gate insulating layer includes a layer of the second dielectric material between a layer of the first dielectric material and the first gate electrode.

18. A method according to claim 17 wherein the layer of the second insulating material has a thickness in the range of about 4 Angstroms to about 20 Angstroms.

19. A method according to claim 16 wherein the first gate insulating layer includes an interface region adjacent the first gate electrode wherein the interface region includes the first and second dielectric materials.

20. A method according to claim 19 wherein the interface region comprises a mixture of the first and second dielectric materials.

21. A method according to claim 16 wherein the second dielectric material comprises a metal oxide.

22. A method according to claim 21 wherein the metal oxide comprises HfO₂, HfSiOₓ, HfSiON, HfAlO, HfYO, HfLaO, HfTiO, and/or HfTaO.

23. A method according to claim 16 wherein the first dielectric material comprises silicon oxide, silicon nitride, and/or silicon oxynitride.
